(19) United States
(12) Patent Application Publication
(10) Pub. No.: US 2011/0056908 A1
(43) Pub. Date: Mar. 10, 2011

(54) METHOD AND APPARATUS FOR MANUFACTURING MAGNETIC RECORDING MEDIUM

(75) Inventors: Masato Fukushima, Chiba-shi (JP); Akira Sakawaki, Ichihara-shi (JP); Tomoo Shige, Chiba-shi (JP)

(73) Assignee: SHOWA DENKO K.K., Minato-ku, Tokyo (JP)

(21) Appl. No.: 12/991,882

(22) PCT Filed: May 12, 2009
(86) PCT No.: PCT/JP2009/058834

§ 371 Date: Nov. 9, 2010

(30) Foreign Application Priority Data
May 13, 2008 (JP) 2008-126245

(51) Int. Cl. H01L 21/308

(52) U.S. Cl. 216/22; 156/345.51

(57) ABSTRACT

There is provided a method for manufacturing a magnetic recording medium which manufactures media by employing the same in-line apparatus and which is capable of reducing the contamination due to the handling and of enhancing the productivity,
the method for manufacturing a magnetic recording medium characterized by including, in the following order: a mounting step where a nonmagnetic substrate onto which at least a magnetic recording layer and a mask layer for patterning the magnetic recording layer have been laminated is mounted on a carrier; a reforming step where a portion of the magnetic recording layer which is not covered with the mask layer is subjected to a reactive plasma treatment or an ion irradiation treatment to reform the magnetic properties, thereby forming a magnetic recording pattern constituted of a remaining magnetic material; a removal step in which the mask layer is removed; a protective film forming step in which a protective film is formed on top of the magnetic recording layer; and a detaching step in which the nonmagnetic substrates are detached from the carrier, wherein any one or more steps among the reforming step, the removal step and the protective film forming step are continuously processed in a plurality of chambers.

### TECHNICAL FIELD

The present invention relates to a method and apparatus for manufacturing a magnetic recording medium used for a hard disk device. More specifically, the present invention relates to a method for manufacturing a so-called discrete medium or patterned medium which has a magnetically separated, magnetic recording area, and also relates to a manufacturing apparatus for implementing the manufacturing method. Priority is claimed on Japanese Patent Application No. 2008-126245, filed May 13, 2008, the content of which is incorporated herein by reference.

### BACKGROUND ART

In recent years, the application range of magnetic recording apparatuses, such as magnetic disk apparatuses, flexible disk apparatuses and magnetic tape apparatuses, has increased considerably, and the importance thereof has also increased. At the same time, an attempt is being made to highly increase the recording density of magnetic recording media used for these apparatuses. In particular, since the introduction of a magnetoresistive (MR) head and a partial response maximum likelihood (PRML) technology, increase in the surface recording density has accelerated even more, and with the introduction of a giant magnetoresistive (GMR) head, a tunnel magnetoresistive (TMR) head or the like in recent years, the recording density has continued to increase at a rate as high as about 100% per year.

Regarding these magnetic recording media, there is a demand for a further increase in the recording density in the future. It is therefore required to achieve a higher coercive force, a higher signal-to-noise ratio (SNR) and a higher resolution for a magnetic layer. In addition, in recent years, attempts to increase the surface recording density have also been constantly made by increasing the track density together with the improvements in the linear recording density.

The most recent magnetic recording devices have a track density of as high as 110 kTPI. However, as the track density increases, magnetically recorded information on adjacent tracks interferes with each other, and as a result, the magnetic transition regions at their boundary regions become a noise source, which may easily impair the SNR. This directly results in deterioration of the bit error rate, which is a drawback for improving the recording density.

In order to increase the surface recording density, it is necessary to make the size of each recording bit on the magnetic recording medium finer and to secure the greatest possible levels of saturation magnetization and magnetic film thickness for each recording bit. However, on the other hand, as the recording bit becomes finer, the minimum magnetization volume per 1 bit becomes small. As a result, the problem of loss of recorded data due to the magnetization reversal by heat fluctuation will occur.

In addition, since the distance between the adjacent tracks will be reduced, a track servo technique with extremely high precision is required in the magnetic recording apparatus, and at the same time, a method is generally employed in which recording is executed widely and reproduction is executed more narrowly than during recording in order to eliminate as much influence as possible from the adjacent tracks. However, although the inter-track influence can be suppressed to the minimum level according to this method, on the other hand, it is difficult to obtain a satisfactory reproduction output with this method, and it is thus difficult to provide an adequate level of SNR.

As one of the methods for solving such a problem of heat fluctuation, of securing an adequate level of SNR, or of securing the sufficient output, an attempt to increase the track density has been made by forming an uneven pattern along the tracks on the surface of a recording medium so as to physically separate the recording tracks from one another. Hereafter, such a technique will be referred to as a discrete track method, and a magnetic recording medium produced by the technique will be referred to as a discrete track medium. In addition, an attempt to manufacture a so-called patterned media in which a data area within the same track is further divided has also been made.

As an example of such a discrete track medium, there is known a magnetic recording medium which is formed on a nonmagnetic substrate having an uneven pattern formed on its surface, and physically separated magnetic recording tracks and a servo signal pattern are formed on the medium (for example, refer to Patent Document 1).

This magnetic recording medium is one in which a ferromagnetic layer is formed on the surface of a substrate which has a plurality of uneven patterns on the surface thereof via a soft magnetic layer, and a protective film is formed on the surface of the ferromagnetic layer. In this magnetic recording medium, a magnetic recording region which is physically isolated from the surroundings thereof is formed in a convex portion.

According to this magnetic recording medium, since the generation of a magnetic wall in the soft magnetic layer can be suppressed, the influence of the heat fluctuation hardly occurs, and there is no interference between adjacent signals. Therefore, it is considered that a high density magnetic recording medium with less noise can be formed.

The discrete track method includes the following two methods. That is, a method of forming tracks after a magnetic recording medium composed of several layers of thin films is formed, and a method of forming thin films of a magnetic recording medium after an uneven pattern is formed directly on the surface of a substrate in advance or on a thin film layer for the formation of tracks (for example, refer to Patent Documents 2 and 3).

Further, a method of forming a region between the magnetic tracks of a discrete track medium by injecting ions of nitrogen, oxygen, or the like into a magnetic layer which is formed in advance, or by irradiating the magnetic layer with a laser beam so as to change the magnetic properties of that irradiated portion has been disclosed (refer to Patent Documents 4 to 6).

In addition, in Patent Document 7, an in-line film forming apparatus for forming a multiple layers of films on top of a substrate by circumferentially conveying a carrier that holds a plurality of substrates when manufacturing a magnetic recording medium has been disclosed.

### PRIOR ART DOCUMENTS

### Patent Documents

[Patent Document 1] Japanese Unexamined Patent Application, First Publication No. 2004-164692

[Patent Document 2] Japanese Unexamined Patent Application, First Publication No. 2004-178793

[Patent Document 3] Japanese Unexamined Patent Application, First Publication No. 2004-178794

[Patent Document 4] Japanese Unexamined Patent Application, First Publication No. Hei 5-205257

[Patent Document 5] Japanese Unexamined Patent Application, First Publication No. 2006-209952

[Patent Document 6] Japanese Unexamined Patent Application, First Publication No. 2006-309841

[Patent Document 7] Japanese Unexamined Patent Application, First Publication No. Hei 8-274142

### DISCLOSURE OF INVENTION

### Problems to be Solved by the Invention

As a manufacturing method of a discrete medium, for example, there is a method of forming a soft magnetic layer, an intermediate layer, a magnetic recording layer, or the like on top of a nonmagnetic substrate, forming a mask layer for forming a magnetic recording region on the surface thereof by using a photolithography technique, exposing a portion of the magnetic recording layer which is not covered with the mask layer to reactive plasma or the like so that the magnetic properties of the portion are reformed, removing the mask layer, and forming a protective film and a lubricant layer thereon.

It is preferable to continuously perform these steps in a single apparatus if possible in that a substrate is prevented from being contaminated when handling the substrate for processing, the number of handling steps and the like can be reduced to enhance the efficiency of the manufacturing steps, and the yield of products can be increased to improve the productivity of the magnetic recording media.

However, among these steps, although the in-line film forming apparatus disclosed in Patent Document 7 can be employed for the step of forming a soft magnetic layer, an intermediate layer, an orientation controlling layer, a magnetic recording layer or the like, and the step of forming a protective film, it has been difficult to add the step of forming a mask layer, the step of exposing a portion of the magnetic recording layer which is not covered with the mask layer to reactive plasma or the like, thereby reforming the magnetic properties of the portion, and the step of removing the mask layer, to the steps using an in-line apparatus for forming films such as magnetic layers.

That is, the film forming step for a magnetic recording layer or the like can be processed in a time period of about 10 seconds for each one substrate, whereas it is difficult to process the step of forming a patterned mask layer on the surface of a magnetic recording layer, the step of partially reforming the magnetic properties of a magnetic recording layer, and the step of removing a mask layer within this time period. Therefore, it has been difficult to continuously perform the respective steps.

In addition, in the step for patterning the mask layer on the surface of the magnetic recording layer, a step for applying a liquid resist to the surface of a magnetic recording layer and stamping a mold onto the surface of the resist to transfer a mold pattern is included in many cases. Since these steps are wet processes and are considerably different from the sputtering step of the magnetic recording layer, which is a dry process, it has been difficult to continuously conduct these steps in one apparatus.

An object of the present invention is to provide a method and an apparatus for manufacturing a magnetic recording medium which solves these problems and manufactures discrete media or the like by employing the same in-line apparatus if possible, and which is capable of reducing the contamination due to the handling of the substrates for processing and of enhancing the productivity in the manufacturing of discrete media or the like.

### Means for Solving the Problems

The present inventors have conducted intensive and extensive studies in order to solve the above problems and discovered the following facts to complete the present invention. That is, in a method for manufacturing a magnetic recording medium that has a magnetically separated, magnetic recording region by sequentially conveying a plurality of nonmagnetic substrates mounted on a carrier into a plurality of connected chambers, by conducting any one of the steps, among the step of subjecting a mask layer to ion etching, the step of subjecting a portion of a magnetic layer which is not covered with the mask layer to a reactive plasma treatment or ion irradiation treatment to thereby reforming the portion, and the step of forming a protective film on top of the magnetic layer, in a plurality of chambers, it becomes possible to continuously conduct the processing of the respective steps at a constant speed, thereby achieving high productivity for the magnetic recording medium.

That is, the present invention relates to the following aspects.

[1] A method for manufacturing a magnetic recording medium having a magnetic recording pattern by sequentially conveying a plurality of nonmagnetic substrates mounted on a carrier into a plurality of chambers that are connected to each other, the method characterized by including, in the following order, a mounting step where a nonmagnetic substrate onto which at least a magnetic recording layer and a mask layer for patterning the magnetic recording layer have been laminated is mounted on a carrier; a reforming step where a portion of the magnetic recording layer which is not covered with the mask layer is subjected to a reactive plasma treatment or an ion irradiation treatment to reform the magnetic properties, thereby forming a magnetic recording pattern constituted of a remaining magnetic material; a removal step in which the mask layer is removed; a protective film forming step in which a protective film is formed on top of the magnetic recording layer; and a detaching step in which the nonmagnetic substrates are detached from the carrier; and any one or more steps among the reforming step, the removal step and the protective film forming step are continuously processed in a plurality of chambers.
[2] The method for manufacturing a magnetic recording medium according to the above aspect [1], characterized in that reforming of the magnetic properties in the reforming step is non-magnetization.
[3] The method for manufacturing a magnetic recording medium according to the above aspect [1] or [2], characterized by conducting a patterning step in which the mask layer is patterned, between the mounting step and the reforming step.
[4] The method for manufacturing a magnetic recording medium according to any one of the above aspects [1] to [3], characterized in that the magnetic recording layer is formed on both sides of the nonmagnetic substrate, and the reactive plasma treatment or the ion irradiation treatment in the reforming step is conducted simultaneously on both sides of the nonmagnetic substrate.
[5] The method for manufacturing a magnetic recording medium according to any one of the above aspects [1] to [4], characterized by conducting the reactive plasma treatment or the ion irradiation treatment by employing any one method selected from the group consisting of an ion gun, ICP and RIE.
[6] An apparatus for manufacturing a magnetic recording medium having a magnetic recording pattern by sequentially conveying a plurality of nonmagnetic substrates mounted on the carrier into a plurality of chambers that are connected to each other, the apparatus characterized by including a mounting mechanism for mounting a nonmagnetic substrate onto which at least a magnetic recording layer and a mask layer for patterning the magnetic recording layer have been laminated on a carrier; a reforming chamber equipped with a mechanism for subjecting a portion of the magnetic recording layer which is not covered with the mask layer is subjected to a reactive plasma treatment or an ion irradiation treatment to reform the magnetic properties, thereby forming a magnetic recording pattern constituted of a remaining magnetic material; a removal chamber for removing the mask layer; a protective film forming chamber equipped with a mechanism for forming a protective film on top of the magnetic recording layer; and a detaching mechanism for detaching the nonmagnetic substrate from the carrier after a film formation, and any one or more components among the reforming chamber, the removal chamber and the protective film forming chamber is provided in plural.
[7] The apparatus for manufacturing a magnetic recording medium according to the above aspect [6], characterized by further including a patterning chamber for patterning the mask layer between the mounting mechanism and the reforming chamber.

### EFFECTS OF THE INVENTION

According to the method and apparatus of the present invention for manufacturing a magnetic recording medium, since many of the steps in the manufacturing of so-called discrete media can be conducted using an in-line manufacturing apparatus, it becomes possible to reduce the number of steps of handling the substrate for processing and to thereby prevent the contamination thereof, and it also becomes possible to improve the productivity of the magnetic recording medium.

### BRIEF DESCRIPTION OF THE DRAWINGS

FIG. 1 is an enlarged, schematic cross sectional view showing a magnetic recording medium which is an embodiment of the present invention.

FIG. 2 is an enlarged, schematic cross sectional view showing a magnetic recording medium which is an embodiment of the present invention.

FIG. 3 is a schematic view showing an example of an apparatus for manufacturing a magnetic recording medium which is an embodiment of the present invention.

FIG. 4 is a schematic view showing a processing chamber and a carrier in the apparatus for manufacturing a magnetic recording medium which is an embodiment of the present invention.

FIG. 5 is a side view showing a carrier provided in the apparatus for manufacturing a magnetic recording medium which is an embodiment of the present invention.

FIG. 6 is a schematic cross sectional view showing a method for manufacturing a magnetic recording medium which is an embodiment of the present invention in the order of manufacturing steps.

FIG. 7 is a schematic cross sectional view showing a method for manufacturing a magnetic recording medium which is an embodiment of the present invention in the order of manufacturing steps.

FIG. 8 is a schematic cross sectional view showing a method for manufacturing a magnetic recording medium which is an embodiment of the present invention in the order of manufacturing steps.

FIG. 9 is a schematic configuration diagram showing an example of a magnetic recording and reproducing apparatus which is an embodiment of the present invention.

### BEST MODE FOR CARRYING OUT THE INVENTION

An embodiment of the present invention will be described below in detail with reference to the drawings.

The present embodiment is applied to a manufacturing method which uses a so-called in-line manufacturing apparatus where a magnetic recording medium having a magnetic recording pattern is manufactured by sequentially conveying a plurality of nonmagnetic substrates mounted onto a carrier to the inside of a plurality of connected chambers.

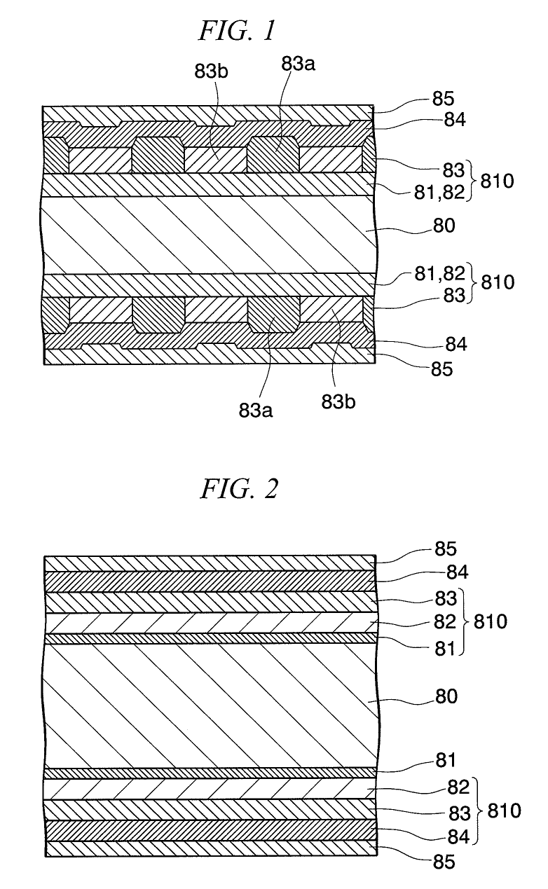

A magnetic recording medium of the present embodiment has, for example, as shown in FIGS. 1 and 2, a structure in which a soft magnetic layer 81, an intermediate layer 82, a magnetic recording layer 83 and a protective film 84 are laminated, and a lubricating film 85 is further formed on the outermost surface thereof, on both sides of a nonmagnetic substrate 80. A magnetic layer 810 is formed of the soft magnetic layer 81, the intermediate layer 82, and the magnetic recording layer 83. As shown in FIG. 1, in the magnetic recording layer 83, a magnetic recording pattern and a nonmagnetic region which are not shown are formed.

As the nonmagnetic substrate 80, any substrate can be used as long as it is a nonmagnetic substrate, such as Al alloy substrates made of, for example, an Al—Mg alloy or the like, which are composed mainly of aluminum, or substrates made of ordinary soda glass, aluminosilicate-based glass, crystallized glass, silicon, titanium, ceramics, and various resins.

Among these, it is preferable to use an Al alloy substrate, a substrate made of glass such as crystallized glass, or a silicon substrate. The average surface roughness (Ra) of these substrates is not more than 1 nm, preferably not more than 0.5 nm and more preferably not more than 0.1 nm.

Although the magnetic layer 810 formed on the surface of the nonmagnetic substrate 80 as described above may be either an in-plane magnetic layer or a perpendicular magnetic layer, a perpendicular magnetic layer is preferable in order to achieve a higher recording density.

It is preferable that the magnetic layer 810 be formed from alloys composed mainly of Co. For example, as a magnetic layer for an in-plane magnetic recording medium, a laminated structure composed of a nonmagnetic CrMo underlayer and a ferromagnetic CoCrPtTa magnetic layer can be used.

In addition, as a magnetic layer for a perpendicular magnetic recording medium, as shown in FIG. 2, for example, a laminated structure constituted of the soft magnetic layer 81 made of a soft magnetic FeCo alloy (such as FeCoB, FeCoSiB, FeCoZr, FeCoZrB and FeCoZrBCu), an FeTa alloy (such as FeTaN and FeTaC) a Co alloy (such as CoTaZr, CoZrNB and CoB) or the like, the intermediate layer 82 made of Ru or the like, and the magnetic recording layer 83 made of a 60Co-15Cr-15Pt alloy or a 70Co-5Cr-15Pt-10SiO₂ alloy can be used. In addition, an orientation control film made of Pt, Pd, NiCr, NiFeCr or the like may be laminated between the soft magnetic layer 81 and the intermediate layer 82.

The thickness of the whole magnetic layer 810 may be set to be equal to or more than 3 nm and equal to or less than 20 nm, preferably equal to or more than 5 nm and equal to or less than 15 nm, and the magnetic layer 810 may be formed so that a sufficient input and output performance of the head can be achieved in accordance with the type and lamination structure of the magnetic alloy used. The thickness of the magnetic layer 810 needs to be equal to or more than a certain thickness in order to obtain predetermined output greater than certain output at the time of reproduction. On the other hand, since various parameters representing the recording and reproducing characteristics are usually impaired as the level of output increases, it is necessary to set the above thickness to the optimum thickness.

In addition, the protective layer 84 may be a carbonaceous layer composed of carbon (C), hydrogenated carbon (H×C), carbon nitride (CN), amorphous carbon, silicon carbide (SiC) or the like, or other materials that are usually employed as a protective film material, such as SiO₂, Zr₂O₃ and TiN. Further, the protective layer 84 may be constituted of two or more layers. The film thickness of the protective layer 84 needs to be less than 10 nm. This is because, if the film thickness of the protective layer 84 exceeds 10 nm, the distance between a head and the magnetic recording layer 83 becomes large, which makes it impossible to obtain sufficient input and output signal intensity.

Furthermore, examples of the lubricant used for the lubricating layer 85 include a fluorine-based lubricant, a hydrocarbon-based lubricant and a mixture thereof, and the lubricating layer 85 is usually formed with a thickness of 1 to 4 nm.

Next, an apparatus for manufacturing a magnetic recording medium according to the present embodiment will be described with reference to the drawings.

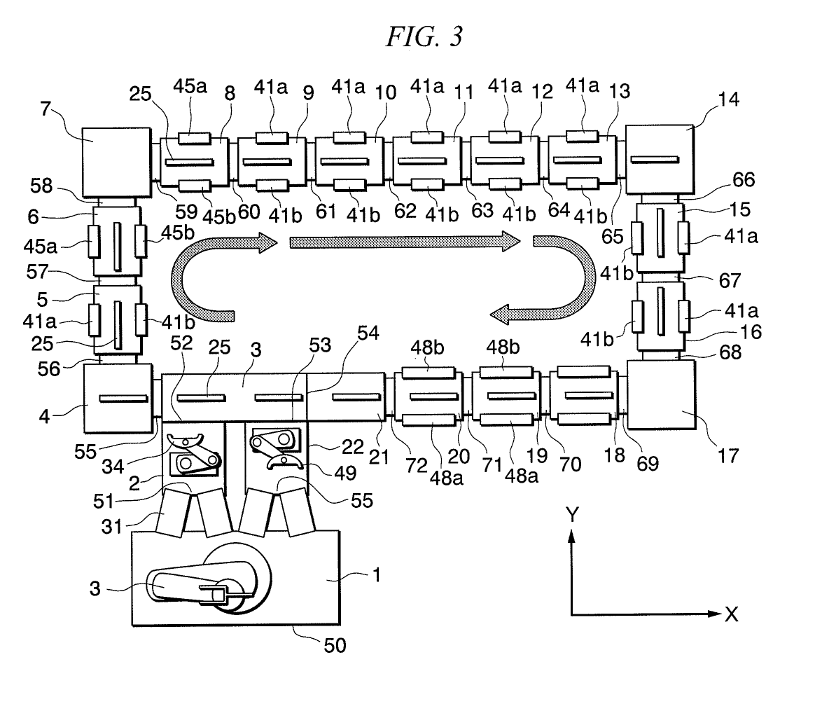

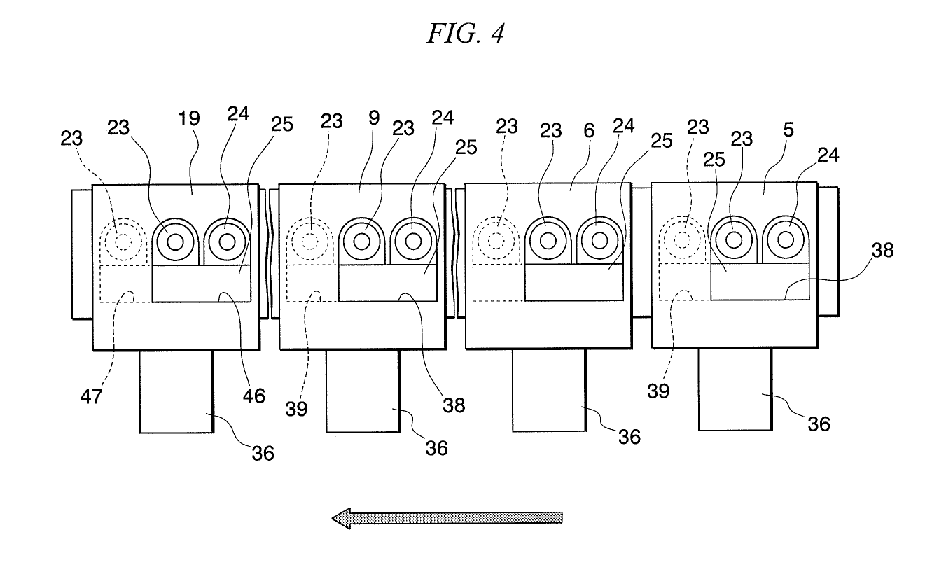

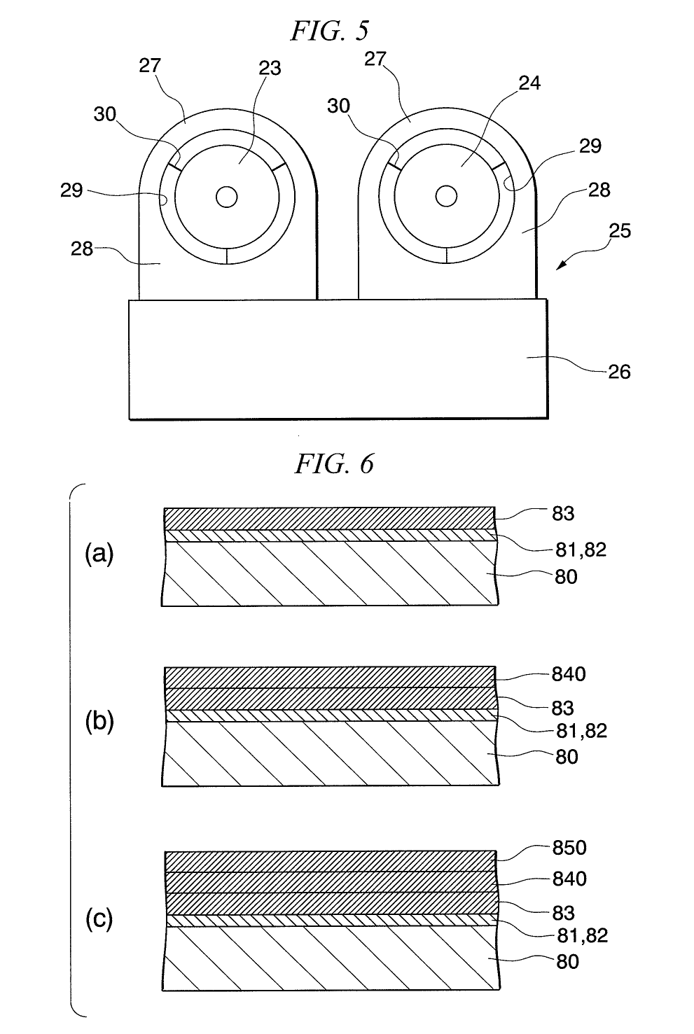

FIG. 3 is a schematic view showing an example of an apparatus for manufacturing a magnetic recording medium, FIG. 4 is a schematic view showing a processing chamber and a carrier in the apparatus for manufacturing a magnetic recording medium, and FIG. 5 is a side view showing a carrier provided in the apparatus for manufacturing a magnetic recording medium.

It should be noted that in FIG. 4, a carrier 25 indicated by the solid line shows a state where the carrier 25 is stopped at a first processing position, whereas a carrier 25 indicated by the broken line shows a state where the carrier 25 is stopped at a second processing position. That is, since the processing chamber shown in the present example has two processing units in places opposite to the nonmagnetic substrate inside the chamber, a nonmagnetic substrate at the left side of the carrier 25 is processed in a state where the carrier 25 is stopped at a first processing position, and then, the carrier 25 is moved to a position indicated by a broken line, and a nonmagnetic substrate at the right side of the carrier 25 is processed in a state where the carrier 25 is stopped at a second processing position. Note that if two processing units are each installed at both sides opposite to the nonmagnetic substrate inside the chamber, such movement of the carrier 25 is not required, and the substrates held at the right side and the left side of the carrier 25 can be processed at the same time.

As shown in FIG. 3, this apparatus for manufacturing a magnetic recording medium includes a robot base 1, a substrate cassette transferring robot 3 mounted on the robot base 1, a substrate supplying robot chamber 2 adjacent to the robot base 1, a substrate supplying robot 34 arranged inside the substrate supplying robot chamber 2, a substrate attaching chamber 52 adjacent to the substrate supplying robot chamber 2, corner chambers 4, 7, 14, and 17 for rotating the carriers, a plurality of processing chambers 5, 6, 8 to 13, 15, 16, and 18 to 20 arranged between the respective corner chambers 4, 7, 14, and 17, a substrate detaching chamber 54, a substrate detaching robot chamber 22 arranged adjacent to the substrate detaching chamber 54, and a substrate detaching robot 49 installed inside the substrate detaching robot chamber 22. In addition, a plurality of carriers 25 onto which a plurality of substrates for being processed (i.e., nonmagnetic substrates) 23 and 24 are mounted are provided internally to each processing chambers 5 and so on.

In the manufacturing apparatus described above, a mounting mechanism is constituted by the robot base 1, the substrate cassette transferring robot 3, the substrate supplying robot chamber 2, the substrate supplying robot 34 and the substrate attaching chamber 52. A nonmagnetic substrate onto which the magnetic layer 810 and a mask layer have been formed is mounted on the carrier 25 by this mounting mechanism.

Furthermore, in the manufacturing apparatus described above, a detachment mechanism is constituted by the robot base 1, the substrate cassette transferring robot 3, the substrate detaching chamber 54, the substrate detaching robot chamber 22 and the substrate detaching robot 49. A nonmagnetic substrate is detached from the carrier 25 by the detachment mechanism.

In addition, in the manufacturing apparatus described above, patterning chambers are constituted by the processing chambers 6 and 8. The patterning chamber is equipped with a mechanism for patterning a mask layer.

Moreover, in the manufacturing apparatus described above, reforming chambers are constituted by the processing chambers 10, 11 and 12. Each reforming chamber is equipped with a mechanism for performing a reactive plasma treatment or an ion irradiation treatment on the region within the magnetic recording layer 83 which is not covered with a mask layer after patterning, thereby reforming the region into a nonmagnetic material, and also forming a magnetic recording pattern composed of the remaining magnetic material.

Further, in the manufacturing apparatus described above, removal chambers are constituted by the processing chambers 16 and 18. The removal chambers are equipped with a mechanism for removing a mask layer.

Furthermore, in the manufacturing apparatus described above, protective film forming chambers are constituted by the processing chambers 19 and 20. The protective film forming chambers are equipped with a mechanism for forming the protective film 84 on the magnetic recording layer 83.

As described above, in the manufacturing apparatus according to the present embodiment, the patterning chamber, the reforming chamber, the removal chamber and the protective film forming chamber are each constituted by a plurality of processing chambers.

In addition, to the respective chambers 2, 52, 4 to 20, 54, and 3A, there are respectively connected vacuum pumps, and it is configured so that the carriers 25 are sequentially transferred to the respective chambers that are decompressed by operation of these vacuum pumps, and both sides of the mounted substrates 23 and 24 are processed inside the respective chambers, thereby manufacturing a magnetic recording medium.

As shown in FIG. 5, the carrier 25 has a supporting base 26, and a plurality of substrate mounting sections 27 (two of these are mounted in the present embodiment) provided on the upper surface of the supporting base 26.

Each of the substrate mounting sections 27 is configured such that in a plate body 28 having a thickness almost the same as the thickness of the substrates for processing (i.e., nonmagnetic substrates) 23 and 24, there is formed a circular through hole 29 with a diameter slightly greater than the outer circumference of the substrates 23 and 24, and around the through hole 29 there are provided a plurality of supporting members 30 that project toward the inner side of the through hole 29. On this substrate mounting section 27, the substrates 23 and 24 are fitted within the through hole 29, and the supporting members 30 engage with the edge section thereof to thereby hold the substrates 23 and 24. These substrate mounting sections 27 are provided in parallel on the upper surface of the supporting base 26 so that the main surfaces of the two of the mounted substrates 23 and 24 are substantially orthogonal to the upper surface of the supporting base 26 while being substantially on the same plane. Hereunder, two of the substrates 23 and 24 for processing to be mounted on these substrate mounting sections 27 will be respectively referred to as the first substrate for processing 23 and the second substrate for processing 24.

The substrate cassette transferring robot 3 supplies the substrate to the substrate attaching chamber 2 from a cassette in which the substrates for processing 23 and 24 are housed, and also takes out a magnetic recording medium which has been detached in the substrate detaching chamber 22. On one side wall of the substrate attaching chamber 2 and the substrate detaching chamber 22, there are respectively provided an opening that opens to the outside and doors 51 and 55 that open and close this opening.

In addition, the respective chambers 2, 52, 4 to 20, 54 and 3A are each connected to two adjacent wall portions, and gate valves are provided at these connecting portions of the respective chambers. When these gate valves are in a closed state, the inside of the respective chambers are respectively independent enclosed spaces.

The corner chambers 4, 7, 14 and 17 are chambers for changing the direction of movement of the carrier 25, and inside thereof, there is provided a mechanism (although not shown in the drawing) that rotates the carrier 25 and moves it to the next chamber.

Each of the chambers is provided with a processing gas supplying pipe, and the processing gas supplying pipes are provided with valves whose opening and closing are controlled by a control mechanism which is not shown. By opening and closing these valves and the gate valves for pumps, the supply of gas from the processing gas supplying pipes, the pressure inside the chambers, and the emission of gas are controlled.

Inside the substrate detaching chamber 54, the first substrate for processing 23 and the second substrate for processing 24 which have been installed on the carrier 25 are detached using the robot 49.

The present embodiment relates to a method for manufacturing a magnetic recording medium having a magnetic recording pattern on the nonmagnetic substrate 80 using the above-mentioned apparatus for manufacturing a magnetic recording medium, and magnetic recording patterns 83a that are separated from one another by nonmagnetic regions 83b are formed in the magnetic recording layer 83 of this magnetic recording medium. The nonmagnetic regions 83b are formed, for example, by partially subjecting the magnetic recording layer 83 to a reactive plasma treatment or an ion irradiation treatment, thereby reforming a magnetic material into a nonmagnetic material.

As described above, the magnetic recording medium of the present embodiment can be obtained by providing a mask layer on the surface of the magnetic recording layer 83 and exposing a portion which is not covered with the mask layer to reactive plasma or the like.

It should be noted that the magnetic recording patterns 83a in the present embodiment includes those in the so-called patterned media in which a magnetic recording pattern is arranged with a certain regularity for each one bit, those in the media in which a magnetic recording pattern is arranged in tracks, and other patterns such as servo signal patterns.

Of the various examples described above, it is preferable to apply the present embodiment to a so-called discrete type magnetic recording medium, in which the magnetic recording patterns 83a are the magnetic recording track and servo signal patterns, from the viewpoint of simplicity in manufacture.

The method for manufacturing a magnetic recording medium according to the present embodiment includes a mounting step for mounting a nonmagnetic substrate on which at least the magnetic recording layer 83 and the mask layer which patterns the magnetic recording layer 83 are laminated onto a carrier, a patterning step for patterning the mask layer, a reforming step for performing a reactive plasma treatment or an ion irradiation treatment on the region of the magnetic recording layer 83 which is not covered with the patterned mask layer, thereby reforming the region into a nonmagnetic material to form a magnetic recording pattern, a removing step for removing the mask layer, a protective layer forming step for forming the protective layer 84 on top of the magnetic recording layer 83, and a detaching step for detaching the nonmagnetic substrate from the carrier in this order, and one or more of the reforming step, the removing step, and the protective layer forming step are continuously performed in each one of a plurality of chambers.

Among the respective steps of the present embodiment, the mounting step and the detaching step can be performed in a processing time of about one second for each one substrate. However, the reforming step and removing step require about several tens of seconds, respectively, and the protective film forming step requires the processing time of about several seconds to about 30 seconds. When these steps are performed so that each of the steps is conducted in one chamber, the reforming step and the removing step become a rate-limiting factor, and it is therefore necessary to synchronize the rates of other processes with those of the reforming step and the removing step.

In the present embodiment, the productivity of the magnetic recording medium is improved by performing the steps whose processing speed becomes a rate-limiting factor among the steps from the reforming step to the protective film forming step in a plurality of chambers, thereby making the processing time between the respective steps as equal as possible. For example, if the processing time of the mounting step and of the detaching step for each one substrate in one chamber is 1 second, the processing time of the reforming step and the removing step is 60 seconds, and the processing time of the protective film forming step is 30 seconds, the total processing time in a case where each process is conducted in a single processing chamber is 60 seconds for each one substrate. Here, as in the present embodiment, if two processing chambers are prepared for each of the reforming step and the removing step, the processing time for each one substrate becomes 30 seconds. Further, if four processing chambers are prepared for each of the reforming step and the removing step, and two processing chambers for the protective film forming step, the processing time for each one substrate becomes 15 seconds.

In the method for manufacturing a magnetic recording medium according to the present embodiment, in order to form a magnetic recording pattern on both sides of the nonmagnetic substrate, it is preferable to simultaneously perform the reactive plasma treatment or ion irradiation treatment on both sides of the nonmagnetic substrate. This is because it is preferable to simultaneously treat both sides of a magnetic recording medium since the magnetic recording medium generally has a magnetic recording layer on both sides thereof.

Normally, the magnetic recording layer 83 is formed as a thin film by a sputtering method. For example, as shown in FIG. 6, after sequentially laminating the soft magnetic layer 81 and the intermediate layer 82 on top of the nonmagnetic substrate 80, at least the magnetic recording layer 83 is formed by a sputtering method (FIG. 6(a)), a mask layer 840 is then formed on top of the magnetic recording layer 83 (FIG. 6(b)), and a resist layer 850 is formed on top of the mask layer 840 (FIG. 6(c)).

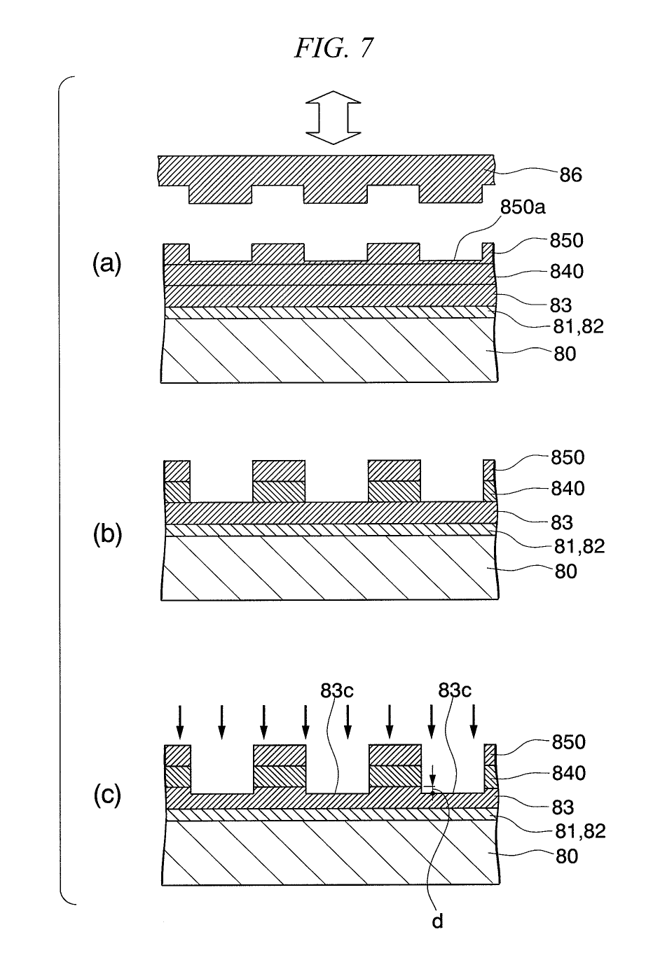

Next, as shown in FIG. 7, a negative pattern of the magnetic recording pattern is transferred to the resist layer 850 using a stamp 86 (FIG. 7(a)). The arrow in FIG. 7(a) indicates the movement of the stamp 86. Next, the nonmagnetic substrate 80 which has been processed so far is mounted onto the carrier 25 within the substrate attaching chamber 52 by the mounting mechanism in the manufacturing apparatus shown in FIG. 3. Then, the nonmagnetic substrate 80 is sequentially conveyed by the carrier, and a mask layer is patterned in the two processing chambers (i.e., patterning chambers) 6 and 8 using the resist layer 850 to which the negative pattern has been transferred (FIG. 7(b)). Next, in the processing chamber 9 shown in FIG. 3, concave portions 83c are formed by partially ion-milling the surface of the magnetic recording layer 83 exposed by the patterning of the mask layer 840 (FIG. 7(c)). In addition, the reference numeral d indicates the depth of the concave portions 83c provided in the magnetic recording layer 83.

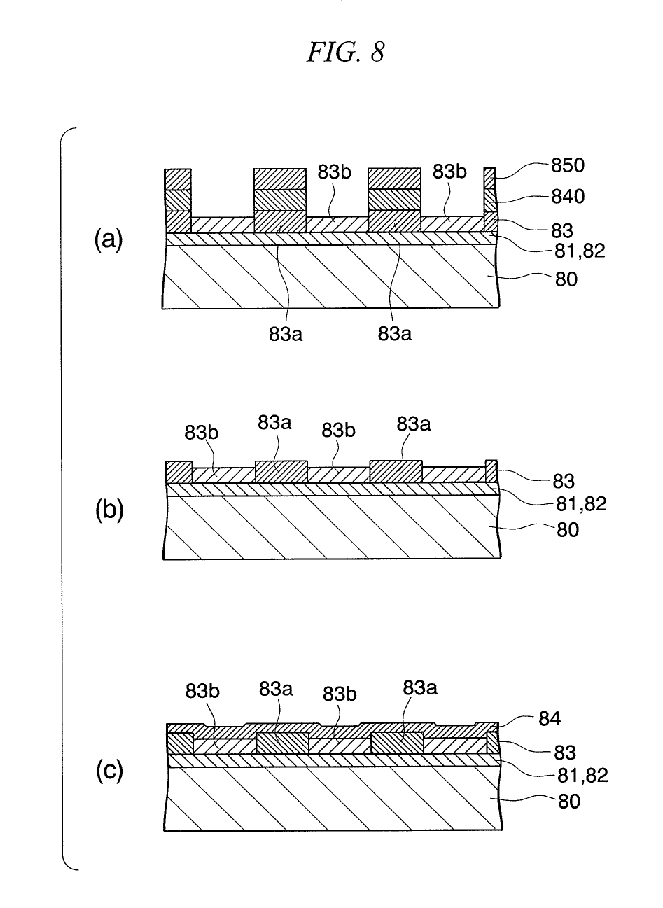

Subsequently, as shown in FIGS. 3 and 8, in the three processing chambers (i.e., reforming chambers) 10, 11, and 12, a magnetic material which constitutes the magnetic recording layer 83 is reformed into a nonmagnetic material by performing a reactive plasma treatment or an ion irradiation treatment on the region of the magnetic recording layer 83 which is not covered with the mask layer 840 (FIG. 8(a)). In this manner, as shown in FIG. 8, the magnetic recording pattern 83a and the nonmagnetic region 83b are formed in the magnetic recording layer 83.

Next, in the two processing chambers 13 and 15, the resist layer 850 is removed, and then, the mask layer 840 is removed in the two processing chambers (i.e., removal chambers) 16 and 18 (FIG. 8(b)). Subsequently, in the two processing chambers 19 and 20, the surface of the magnetic recording layer 83 is covered with the protective film 84 (FIG. 8(c)). The magnetic recording medium of the present embodiment can be manufactured by sequentially conducting the above steps.

The mask layer 840 formed on top of the magnetic recording layer 83 in the step shown in FIG. 6(b) is preferably formed using a material containing at least one selected from the group consisting of Ta, W, Ta nitrides, W nitrides, Si, SiO₂, Ta₂O₅, Re, Mo, Ti, V, Nb, Sn, Ga, Ge, As and Ni. By using such a material, the shielding properties of the mask layer 840 with respect to milling ions can be improved, and the concave portions 83c can be provided in the magnetic recording layer 83.

In addition, the properties for forming the magnetic recording pattern 83a using the mask layer 840 can also be improved. Furthermore, since the above-mentioned substances are easily dry-etched using reactive gas, in the removing step of the mask layer 840 shown in FIG. 8(b), an amount of the residue and thus contamination on the surface of the magnetic recording medium can be reduced.

In the method for manufacturing a magnetic recording medium according to the present embodiment, among these substances, it is preferable to use As, Ge, Sn or Ga as the mask layer 840, more preferably Ni, Ti, V or Nb, and most preferably Mo, Ta or W.

Further, in the method for manufacturing a magnetic recording medium according to the present embodiment, in the step shown in FIG. 7(a), it is preferable to set the thickness of a remaining portion 850a of the resist layer 850 after the transfer of the negative pattern to the resist layer 850 by the stamp 86 within a range from 0 to 10 nm.

In this case, by setting the thickness of the remaining portion 850a of the resist layer 850 within this range, in the step for patterning the mask layer 840 shown in FIG. 7(b), the sagging of an edge portion of the mask layer 840 can be eliminated, the shielding properties of the mask layer 840 with respect to milling ions can be improved, and the concave portions 83c can be provided in the magnetic recording layer 83. In addition, the properties for forming the magnetic recording pattern 83a using the mask layer 840 can also be improved.

In the method for manufacturing a magnetic recording medium according to the present embodiment, it is preferable to employ a radiation-curable material as the material constituting the resist layer 850, and to irradiate the resist layer 850 with radiations when a pattern is transferred to the resist layer 850 by using the stamp 86, or after the pattern transferring step.

By using such a manufacturing method, it is possible to transfer the shape of the stamp 86 to the resist layer 850 with high precision. As a result, in the step for patterning the mask layer 840 in FIG. 7(b), sagging of an edge portion of the mask layer 840 can be eliminated, the shielding properties of the mask layer 840 with respect to implanted ions can be improved, and the properties for forming the magnetic recording pattern 83a using the mask layer 840 can also be improved.

The term “radiation” used in the present embodiment is a concept that includes a wide range of electromagnetic waves, such as heat ray, visible light, ultraviolet ray, X-ray and gamma ray. In addition, radiation-curable materials refer to, for example, a thermosetting resin when the radiation is heat ray and an ultraviolet curing resin when the radiation is ultraviolet ray.

In the method for manufacturing a magnetic recording medium according to the present embodiment, in particular, in the step for transferring a pattern to the resist layer 850 by using the stamp 86, it is possible to transfer the shape of the stamp 86 to the resist layer 850 with high precision by pressing the stamp against the resist layer 850 in a state where the fluidity of the resist layer is high, irradiating the resist layer 850 with radiations while the stamp being pressed to cure the resist layer 850, and then, separating the stamp 86 from the resist layer 850.

As a method for irradiating the resist layer 850 with radiations while pressing the stamp 86 against the resist layer 850, a method of irradiating the resist layer with radiations from the opposite side of the stamp 86, i.e., from the side of the nonmagnetic substrate 80, a method of selecting a substance which can transmit radiations as the material constituting the stamp 86 and irradiating the resist layer with radiations from the side of the stamp 86, a method of irradiating the resist layer with radiations from the side surface of the stamp 86, and a method of irradiating the resist layer with radiations by the heat conduction via the stamp 86 or the nonmagnetic substrate 80 by using highly conductive radiations with respect to a solid material, such as heat ray can be used.

In the method for manufacturing a magnetic recording medium according to the present embodiment, among these methods, it is particularly preferable to use an ultraviolet curable resin such as a novolak-based resin, an acrylic ester or an alicyclic epoxy as the material constituting the resist layer 850, and to use glass or resin having high transmittance with respect to the ultraviolet rays as the material constituting the stamp 86.

By using such methods, it is possible to reduce the levels of coercive force and residual magnetization of the magnetic recording pattern 83a to the utmost limit, and it is possible to prevent the bleeding during magnetic recording and to provide a magnetic recording medium having a high in-plane recording density.

As the stamp 86 used in the above processes, for example, a stamp in which a fine track pattern is formed on a metal plate by using a method, such as electron beam lithography, can be used. As the material for the stamp, a material with the hardness and durability which can withstand the processes is required. For example, Ni or the like can be used, although the material is not particularly limited as long as it meets the aforementioned object. In addition to the tracks used to record ordinary data, servo signal patterns, such as burst patterns, gray code patterns and preamble patterns, can also be formed on the stamp 86.

In the present embodiment, as shown in FIG. 7(c), the concave portions 83c are provided by removing a portion of the surface layer of the magnetic recording layer 83 by ion milling or the like. As described above, when the surface of the magnetic recording layer 83 is exposed to the reactive plasma or the reactive ion to reform the magnetic properties of the magnetic recording layer 83 after providing the concave portions 83c, the contrast between the magnetic recording pattern 83a and the pattern of the nonmagnetic regions 83b becomes clearer, and the S/N ratio of a magnetic recording medium can also be improved, as compared to the case where the concave portions 83c are not provided. The reason for this is presumed as follows. Since the surface layer portion of the magnetic recording layer 83 is removed, the surface thereof is cleaned and activated, and thus reactivity with the reactive plasma or the reactive ions is increased. Further, since defects, such as voids, are introduced to the surface layer portion of the magnetic recording layer 83, the reactive ions easily penetrate into the magnetic recording layer 83 through the defects.

In the present embodiment, the depth d up to which a portion of the surface layer of the magnetic recording layer 83 is removed by ion milling or the like is preferably set within the range from 0.1 nm to 15 nm, and more preferably within the range from 1 to 10 nm. In those cases where the removal depth by the ion milling is less than 0.1 nm, the effect of removal of the magnetic recording layer 83 mentioned above will not be achieved. On the other hand, in those cases where the removal depth is greater than 15 nm, surface smoothness of the magnetic recording medium deteriorates and thus the floating properties of the magnetic head deteriorates when producing a magnetic recording and reproducing apparatus.

The present embodiment is characterized, for example, by forming a region that magnetically separates the magnetic recording track and the servo signal pattern portion by exposing a magnetic recording layer on which films have already been formed to the reactive plasma or the reactive ions, thereby reforming the magnetic properties of the magnetic recording layer.

As shown in FIG. 8(a), the magnetic recording patterns 83a in the present embodiment refers to a state where the magnetic recording layer 83 is separated by the nonmagnetic regions 83b which have been non-magnetized, when viewing the magnetic recording medium from the surface side. In other words, in those cases where the magnetic recording layer 83 is separated when viewed from the surface side, it is possible to achieve the object of the invention even if the magnetic recording layer 83 is not separated at the bottom thereof, and thus these cases also fall within the concept of the magnetic recording pattern 83a adopted in the present invention. In addition, the term “magnetic recording patterns 83a” used in the present invention includes those in the so-called patterned media in which a magnetic recording pattern is arranged with a certain regularity for each one bit, those in the media in which a magnetic recording pattern is arranged in tracks, and other patterns such as servo signal patterns.

Of the various examples described above, it is preferable to apply the present embodiment to a so-called discrete type magnetic recording medium, in which the magnetic recording patterns 83a are the magnetic recording track and servo signal patterns, from the viewpoint of simplicity in manufacture.

In the present embodiment, reforming of the magnetic recording layer 83 for the sake of forming the magnetic recording pattern 83a refers to causing a partial change in, for example, coercive force and residual magnetization of the magnetic recording layer 83 in order to pattern the magnetic recording layer 83, and the change refers to decrease in the coercive force and decrease in the residual magnetization.

In the present embodiment, in terms of the reforming of the magnetic properties in particular, it is preferable to adopt a method in which the level of magnetization of the magnetic recording layer 83 in the region exposed to the reactive plasma or reactive ion is set to 75% or less, and more preferably 50% or less than the original (untreated) level, and the level of coercive force is set to 50% or less, and more preferably 20% or less than the original level. By manufacturing a discrete track type magnetic recording medium using such methods, it is possible to prevent the bleeding when magnetic recording is conducted on this medium and to provide a magnetic recording medium having a high in-plane recording density.

Furthermore, in the present embodiment, regions (nonmagnetic regions 83b) which separate a magnetic recording track and a servo signal pattern portion can also be achieved by exposing a magnetic recording layer onto which a film has already been formed to the reactive plasma or reactive ions, thereby making the magnetic recording layer 83 amorphous. Reforming of the magnetic properties of the magnetic recording layer in the present invention also includes alteration of the crystal structure of the magnetic recording layer.

In the present invention, making the magnetic recording layer 83 amorphous refers to making the atomic arrangement of the magnetic recording layer 83 into an irregular atomic arrangement with no long distance order, and more specifically, refers to randomly arranging microcrystalline grains having diameters less than 2 nm. When confirming the state of the atomic arrangement by an analytical process, a state is obtained through X-ray diffraction or electron diffraction in which no peaks representing crystal faces are recognized and only a halo is recognized.

Examples of the reactive plasma used in the present embodiment include inductively coupled plasma (ICP) and reactive ion plasma (RIE).

Further, examples of the reactive ion used in the present embodiment include the reactive ion present in the inductively coupled plasma and reactive ion plasma mentioned above.

The inductively coupled plasma refers to high-temperature plasma obtained by applying a high voltage to gas, thereby forming plasma, and further generating the Joule's heat by an eddy current inside the plasma by a varying magnetic field of high frequency. The inductively coupled plasma has high electron density and thus enables the reforming of magnetic properties at high efficiency in a magnetic film with a large area, as compared to the conventional case where discrete track media are manufactured using an ion beam.

The reactive ion plasma is the highly reactive plasma in which a reactive gas, such as O₂, SF₆, CHF₃, CF₄ and CCl₄, is added to the plasma. By using such plasma as the reactive plasma in the present embodiment, it is possible to achieve the reforming of the magnetic properties of the magnetic recording layer 83 with higher efficiency.

In the present embodiment, the magnetic recording layer 83 is reformed by exposing the magnetic recording layer 83 onto which a film has been formed to the reactive plasma. However, it is preferable that this reforming be achieved by the reaction between magnetic metal which constitutes the magnetic recording layer 83 and atoms or ions in the reactive plasma.

The term “reaction” used herein includes alteration of the crystal structure of the magnetic metal, alteration of the composition of the magnetic metal, oxidation of the magnetic metal, nitridation of the magnetic metal and silication of the magnetic metal, among others, due to penetration of atoms or the like in the reactive plasma into the magnetic metal.

In the present embodiment, in particular, it is preferable to oxidize the magnetic recording layer 83 by adding oxygen atoms in the reactive plasma and causing a reaction between the magnetic metal which constitutes the magnetic recording layer 83 and the oxygen atoms in the reactive plasma. This is because it is possible to efficiently reduce the levels of residual magnetization, coercive force or the like in an oxidized portion by partially oxidizing the magnetic recording layer 83, and it is therefore possible to manufacture a magnetic recording medium which has a magnetic recording pattern through the short-time reactive plasma treatment.

In the present embodiment, it is preferable to make halogen atoms contained in the reactive plasma. In addition, it is particularly preferable to use fluorine (F) atoms as the halogen atoms. The halogen atoms may be used by being added to the reactive plasma together with oxygen atoms, or may be added to the reactive plasma without using oxygen atoms. As described above, by adding oxygen atoms or the like to the reactive plasma, it is possible to reform the magnetic properties of the magnetic recording layer 83 due to the reaction between a magnetic metal constituting the magnetic recording layer 83 and oxygen atoms or the like. At this time, it is possible to further enhance this reactivity by adding the halogen atoms to the reactive plasma.

In addition, even when the oxygen atoms are not added in the reactive plasma, the halogen atoms react with a magnetic alloy, and thus, the magnetic properties of the magnetic recording layer 83 can be reformed. The reason for this observation is not yet clear in detail. However, it is thought that the halogen atoms in the reactive plasma etch the foreign substances formed on the surface of the magnetic recording layer 83, as a result of which the surface of the magnetic recording layer 83 is cleaned, thereby enhancing the reactivity of the magnetic recording layer 83.

In addition, it is also possible that the cleaned surface of the magnetic layer reacts with the halogen atoms at high efficiency. It is particularly preferable to use fluorine (F) atoms as the halogen atoms having such an effect.

In the present embodiment, thereafter, it is preferable to adopt a step of removing the resist layer 850 and the mask layer 840 as shown in FIG. 8(b) and then applying a lubricant (not shown) following formation of the protective layer 84 as shown in FIG. 8(c) to manufacture a magnetic recording medium.

For the removal of the resist layer 850 and the mask layer 840, a technique such as dry etching, reactive ion etching, ion milling, or wet etching can be employed.

Although the protective film 84 is generally formed by forming a thin film of Diamond Like Carbon by employing P-CVD or the like, the method is not particularly limited thereto.

In this case, the protective layer 84 may be a carbonaceous layer composed of carbon (C), hydrogenated carbon (H×C), carbon nitride (CN), amorphous carbon, silicon carbide (SiC) or the like, or other materials that are usually employed as a protective film material, such as SiO₂, Zr2O3 and TiN. Further, the protective layer 84 may be constituted of two or more layers.

The film thickness of the protective layer 84 needs to be less than 10 nm. This is because, if the film thickness of the protective layer 84 exceeds 10 nm, the distance between a head and the magnetic recording layer 83 becomes large, which makes it impossible to obtain sufficient input and output signal intensity.

It is preferable to form a lubricating layer 85 on top of the protective layer 84. Examples of the lubricant used for the lubricating layer 85 include a fluorine-based lubricant, a hydrocarbon-based lubricant and a mixture thereof, and the lubricating layer 85 is usually formed with a thickness of 1 to 4 nm.

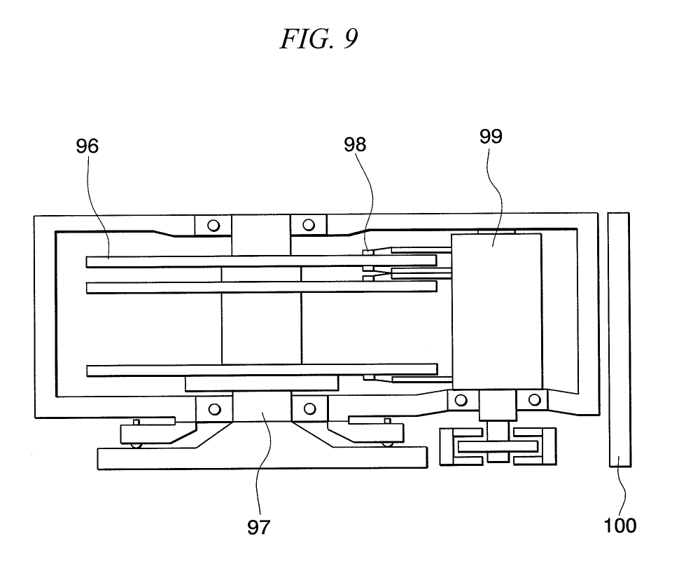

FIG. 9 shows an example of a magnetic recording and reproducing apparatus using the magnetic recording medium described above. The magnetic recording and reproducing apparatus shown here includes a magnetic recording medium 96 configured as described above, a medium driving unit 97 which rotationally drives the magnetic recording medium 96, a magnetic head 98 for recording data in or reproducing data from the magnetic recording medium 96, a head driving unit 99, and a magnetic reproducing signal processing system 100. The magnetic reproducing signal processing system 100 processes input data, transmits recording signals to the magnetic head 98, processes the reproducing signal from the magnetic head 98 and outputs the processed data.

According to the manufacturing method and manufacturing apparatus described above, processes from the reforming of the magnetic recording layer 83 to the formation of the protective layer 84 can be continuously performed using one apparatus, a substrate to be processed is not contaminated when the substrate is handled, the number of handling steps and the like can be reduced to enhance the efficiency of the manufacturing process, and the yield of products can be improved to enhance the productivity of magnetic recording media.

In addition, according to the above manufacturing method and manufacturing apparatus, a step for exposing the region of a magnetic recording layer which is not covered with a mask layer to the reactive plasma or the like, thereby reforming the magnetic properties of this region, and a step for removing the mask layer are shared and conducted in a plurality of processing chambers. Thus, these processes can be easily introduced into an in-line film forming apparatus.

That is, the film forming step for a magnetic recording layer and the like can be processed in a time period of about 10 seconds for each one substrate, whereas it is difficult to process the step for partially reforming the magnetic properties of a magnetic recording layer or the step for removing a mask layer within this time period. Therefore, the reforming step and removing step are shared and performed by a plurality of processing chambers, respectively, so that the processing time of these steps can be synchronized with the processing time of the film forming step for a magnetic recording layer and the like, and thereby, the respective steps can be continuously conducted.

In addition, in the step for patterning the mask layer on the surface of the magnetic recording layer, a wet process for applying a liquid resist to the surface of a magnetic recording layer and stamping a mold onto the surface of the resist to transfer a mold pattern is included. In the manufacturing method and manufacturing apparatus described above, since all the steps other than the application of the resist are dry processes, these steps can be conducted continuously in one manufacturing apparatus in combination with a sputtering step of the magnetic recording layer, which is also a dry process.

### EXAMPLES

Although the present invention will be described below in more detail using a series of Examples, the present invention is in no way limited to the Examples described below.

As shown in FIGS. 1 and 2 and FIGS. 6 to 8, a vacuum chamber with a glass substrate for the HD serving as a nonmagnetic substrate 80 being set therein was evacuated to a pressure of 1.0×10⁻⁵ Pa or less in advance. The glass substrate used herein was made of a crystallized glass including Li₂Si₂O₅, Al₂O₃—K₂O, MgO—P₂O₅ and Sb₂O₃—ZnO as constituting components, and had an outer diameter of 65 mm, an inner diameter of 20 mm and an average surface roughness (Ra) of 2 angstrom.

As shown in FIG. 2, FeCoB to be served as a soft magnetic layer 81, Ru to be served as an intermediate layer 82, and a 70Co-5Cr-15Pt-10SiO₂ alloy to be served as a magnetic recording layer 83 were laminated in this order on the glass substrate using a DC sputtering process. The thickness of the FeCoB soft magnetic layer was 600 Å, the thickness of the Ru intermediate layer was 100 Å and the thickness of the magnetic recording layer was 150 Å. In this manner, a magnetic layer was formed.

A mask layer 840 was then formed thereon by a sputtering process as shown in FIG. 6 (a) to (c). The mask layer 840 was constituted of Ta and the thickness thereof was 60 nm. Subsequently, a resist layer 850 was applied thereon by a spin coating method. A novolak-based resin which was an ultraviolet curable resin was used for the resist layer 850. Further, the thickness of the resist layer was set to 100 nm.

As shown in FIG. 7 (a) to (c), a glass stamp 86 having a negative pattern of a magnetic recording pattern was prepared, and the stamp 86 was pressed against the resist layer 850 at a pressure of 1 MPa (about 8.8 kgf/cm²). In this state, the resist layer was irradiated with a UV ray having a wavelength of 250 nm for 10 seconds from above the glass stamp having a UV transmittance of not less than 95% so as to cure the resist layer.

Then, the stamp 86 was separated from the resist layer 850. In this manner, the magnetic recording pattern was transferred to the resist layer. The pattern transferred to the resist layer 850 had convex portions with a 120 nm-wide circular shape and concave portions with a 120 nm-wide circular shape. The thickness of the resist layer was 80 nm and the thickness of the remaining portion 850a constituting the concave portion of the resist layer was about 5 nm. In addition, the angle of a side wall surface which constitutes the concave portion of the resist layer with respect to the substrate surface was about 90 degrees.

The processed substrate manufactured by the steps as described above was loaded in the apparatus for manufacturing a magnetic recording medium shown in FIGS. 3 to 5. The carrier 25 of the manufacturing apparatus has a structure so that 2 pieces of substrates for processing can be installed at the same time as shown in FIG. 5. In addition, this manufacturing apparatus was configured so that the step of mounting the substrate for processing onto the carrier 25 was conducted in one processing chamber 52, the removal of the remaining portion 850a of the concave portion of the resist layer was conducted in one processing chamber 5, the step of patterning the mask layer was conducted in two processing chambers 6 and 8 (i.e., the patterning chambers), and the step of partially removing the surface of the magnetic recording layer was conducted in one processing chamber 9.

Further, this manufacturing apparatus was configured so that the step of partially reforming the magnetic recording layer was conducted in three processing chambers 10, 11 and 12 (i.e., the reforming chambers), the step of removing the resist was conducted in two chambers 13 and 15, the step of removing the mask layer was conducted in two processing chambers 16 and 18 (i.e., the removal chambers), and the film forming step of a carbon protective film was conducted in two processing chambers 19 and 20 (i.e., the protective film forming chambers). Moreover, this manufacturing apparatus was configured so that the step of detaching the substrate for processing from the carrier was conducted in one processing chamber 54. The processing time in each chamber was not longer than 15 seconds. Hereafter, the details of the respective steps will be described.

In the step of mounting the substrate for processing onto a carrier, the substrate for processing was mounted onto the carrier 25 at a speed of 1.5 seconds/substrate in the chamber 52.

Further, in the step of removing the concave portion of the resist layer, the carrier on which the substrate for processing has been mounted was rotated in a corner chamber 4 and transferred to the processing chamber 5 where the step of removing the concave portion of the resist layer is conducted, thereby removing the region of the concave portion of the resist layer by dry etching. In terms of the conditions for dry etching, the resist was etched using O₂ gas of 40 sccm, a pressure of 0.3 Pa, a high-frequency plasma power of 300 W, a DC bias of 30 W and an etching time of 15 seconds.

In the step of patterning the mask layer, the processed substrate which had been subjected to etching was transferred sequentially to the two processing chambers 6 and 8 in which the step of patterning the mask layer is conducted, and the region in the mask layer made of Ta which was not covered with the resist was removed through dry etching. In terms of the conditions for dry etching, the resist was etched using O₂ gas of 40 sccm, a pressure of 0.3 Pa, a high-frequency plasma power of 300 W, a DC bias of 30 W and an etching time of 10 seconds, whereas the Ta layer was etched using CF₄ gas of 50 sccm, a pressure of 0.6 Pa, a high-frequency plasma power of 500 W, a DC bias of 60 W, and an etching time of 15 seconds in each one chamber and 30 seconds in total.

Further, in the step of partially removing the surface of the magnetic recording layer, the processed substrate which had been subjected to dry etching was transferred to the processing chamber 9 where the magnetic recording layer was partially removed, and the surface of a region in the magnetic recording layer which was not covered with the mask layer was removed by ion milling. Ar ions were used for the ion milling process, and the amount of Ar ions was set to 5×10¹⁶ atoms/cm², the acceleration voltage was set to 20 keV, the milling depth of the magnetic recording layer was set to 0.1 nm, and the ion milling time was set to 5 seconds.

Next, in the step of partially reforming the magnetic recording layer, the processed substrate which had been subjected to ion milling was sequentially transferred to the three processing chambers 10, 11, and 12 in which the magnetic recording layer was partially reformed, and the surface of the region in the magnetic recording layer which was not covered with the mask layer was exposed to the reactive plasma, thereby reforming the magnetic properties. An inductively coupled plasma device available from ULVAC, Inc. was used in the reactive plasma treatment of the magnetic recording layer. In terms of the gas and conditions used for generating plasma, O₂ was used (90 cc/min) with a supplied power for plasma generation of 200 W and a pressure inside the apparatus of 0.5 Pa, and the magnetic layer was processed for 15 seconds in each one chamber and 45 seconds in total in three chambers.

Next, in the step of removing the resist layer, the processed substrate which had been subjected to the reforming treatment was transferred to the two processing chambers 13 and 15 where the resist layer was removed, and the resist layer was removed through dry etching. In terms of the conditions for dry etching, the resist was etched using O₂ gas of 40 sccm, a pressure of 0.3 Pa, a high-frequency plasma power of 300 W, a DC bias of 30 W and an etching time of 15 seconds.

Next, in the step of removing the mask layer, the processed substrate from which the resist layer had been removed was transferred to the two processing chambers 16 and 18 where the mask layer was removed, and the mask layer was removed by dry etching. In terms of the conditions for dry etching, the resist was etched using O₂ gas of 40 sccm, a pressure of 0.3 Pa, a high-frequency plasma power of 300 W, a DC bias of 30 W and an etching time of 10 seconds, whereas the Ta layer was etched using CF₄ gas of 50 sccm, a pressure of 0.6 Pa, a high-frequency plasma power of 500 W, a DC bias of 60 W and an etching time of 15 seconds in each one chamber and 30 seconds in total in two chambers.

Next, in the step of forming the carbon protective film, the processed substrate from which the mask layer had been removed was sequentially transferred to the two processing chambers 19 and 20, and 5 nm of a carbon protective film was formed on top of the magnetic layer by the CVD method. The film forming time was set to 15 seconds.

Finally, in the step of detaching the processed substrate from the carrier, the processed substrate which had been subjected to film forming treatment was transferred to the processing chamber 54 in which the processed substrate was detached from the carrier, and the processed substrate was detached from the carrier 25 at a speed of 1.5 seconds/substrate.

As described above, according to the method and apparatus of the present invention for manufacturing a magnetic recording medium, since many of the steps in the manufacturing of so-called discrete media can be conducted using an in-line manufacturing apparatus, it becomes possible to reduce the number of steps of handling the substrate for processing and to thereby prevent the contamination thereof, and the productivity of the magnetic recording medium can be improved.

### INDUSTRIAL APPLICABILITY

The present invention can be applied to a method and apparatus for manufacturing a magnetic recording medium used for a hard disk device. More specifically, the present invention can be applied to a method for manufacturing a so-called discrete medium or patterned medium which has a magnetically separated, magnetic recording area, and can also be applied to a manufacturing apparatus for implementing the manufacturing method.

### DESCRIPTION OF THE REFERENCE SYMBOLS

1: Substrate cassette transferring robot base (mounting mechanism, detaching mechanism)
2: Substrate supplying robot chamber (mounting mechanism)
3: Substrate cassette transferring robot (mounting mechanism, detaching mechanism)
5, 6, 8 to 13, 15, 16, 18 to 20: Processing chambers (chambers)
6, 8: Processing chambers (patterning chambers)
10 to 12: Processing chambers (reforming chambers)
16, 18: Processing chambers (removing chambers)
19, 20: Processing chambers (protective film forming chambers)
22: Substrate detaching robot chamber (detaching mechanism)
25: Carrier
34: Substrate supplying robot (mounting mechanism)
49: Substrate detaching robot (detaching mechanism)
52: Substrate attaching chamber (mounting mechanism)
54: Substrate detaching chamber (detaching mechanism)
80: Nonmagnetic substrate
83: Magnetic recording layer
83a: Magnetic recording patterns
84: Protective layer
810: Magnetic layer
840: Mask layer

1. A method for manufacturing a magnetic recording medium having a magnetic recording pattern by sequentially conveying a plurality of nonmagnetic substrates mounted on a carrier into a plurality of chambers that are connected to each other,
the method comprising, in the following order:
a mounting step where a nonmagnetic substrate onto which at least a magnetic recording layer and a mask layer for patterning the magnetic recording layer have been laminated is mounted on a carrier;
a reforming step where a portion of the magnetic recording layer which is not covered with the mask layer is subjected to a reactive plasma treatment or an ion irradiation treatment to reform the magnetic properties, thereby forming a magnetic recording pattern constituted of a remaining magnetic material;
a removal step in which the mask layer is removed;
a protective film forming step in which a protective film is formed on top of the magnetic recording layer; and
a detaching step in which the nonmagnetic substrates are detached from the carrier,
wherein any one or more steps among the reforming step, the removal step and the protective film forming step are continuously processed in a plurality of chambers.

2. The method for manufacturing a magnetic recording medium according to claim 1, wherein reforming of the magnetic properties in the reforming step is non-magnetization.

3. The method for manufacturing a magnetic recording medium according to claim 1,
wherein a patterning step in which the mask layer is patterned is conducted between the mounting step and the reforming step.

4. The method for manufacturing a magnetic recording medium according to claim 1,
wherein the magnetic recording layer is formed on both sides of the nonmagnetic substrate, and
the reactive plasma treatment or the ion irradiation treatment in the reforming step is conducted simultaneously on both sides of the nonmagnetic substrate.

5. The method for manufacturing a magnetic recording medium according to claim 1,
wherein the reactive plasma treatment or the ion irradiation treatment is conducted by employing any one method selected from the group consisting of an ion gun, ICP and RIE.

6. An apparatus for manufacturing a magnetic recording medium having a magnetic recording pattern by sequentially conveying a plurality of nonmagnetic substrates mounted on the carrier into a plurality of chambers that are connected to each other,
the apparatus comprising:
a mounting mechanism for mounting a nonmagnetic substrate onto which at least a magnetic recording layer and a mask layer for patterning the magnetic recording layer have been laminated on a carrier;
a reforming chamber equipped with a mechanism for subjecting a portion of the magnetic recording layer which is not covered with the mask layer is subjected to a reactive plasma treatment or an ion irradiation treatment to reform the magnetic properties, thereby forming a magnetic recording pattern constituted of a remaining magnetic material;
a removal chamber for removing the mask layer;
a protective film forming chamber equipped with a mechanism for forming a protective film on top of the magnetic recording layer; and
a detaching mechanism for detaching the nonmagnetic substrate from the carrier after a film formation,
wherein any one or more components among the reforming chamber, the removal chamber and the protective film forming chamber is provided in plural.

7. The apparatus for manufacturing a magnetic recording medium according to claim 6, further comprising a patterning chamber for patterning the mask layer between the mounting mechanism and the reforming chamber.
